(19) United States
(12) Patent Application Publication
(10) Pub. No.: US 2026/0068730 A1
(43) Pub. Date: Mar. 5, 2026

(54) SEMICONDUCTOR PACKAGE

(71) Applicant: Samsung Electronics Co., Ltd., Suwon-si (KR)

(72) Inventors: Hyeonjae Kim, Suwon-si (KR); Yongjae Kim, Suwon-si (KR); Yukyung Park, Suwon-si (KR); Semin Oh, Suwon-si (KR); Seungkwan Ryu, Suwon-si (KR)

(21) Appl. No.: 19/060,142

(22) Filed: Feb. 21, 2025

(30) Foreign Application Priority Data
Aug. 28, 2024 (KR) 10-2024-0115543

(51) Int. Cl. H01L 23/00; H01L 23/498; H01L 25/07

(52) U.S. Cl. CPC H01L 24/14

(57) ABSTRACT

A semiconductor package includes a first substrate including upper pads, at least one chip structure including connection pads, and first bump structures electrically connecting the connection pads and the upper pads. The connection pads include a first group of connection pads arranged at a first interval, and a second group of connection pads arranged at a second interval, smaller than the first interval. Each of the first group of the first bump structures includes a first pillar contacting one of the first group of the connection pads, and a first solder connecting the first pillar and one of the upper pads. Each of the second group of the first bump structures includes a second pillar contacting one of the second group of the connection pads, a second solder contacting one of the upper pads, and a third pillar connecting the second pillar and the second solder.

### CROSS-REFERENCE TO RELATED APPLICATION(S)

This application claims the benefit of priority under 35 U.S.C. § 119 (a) of Korean Patent Application No. 10-2024-0115543, filed on Aug. 28, 2024, in the Korean Intellectual Property Office, the entire disclosure of which is incorporated herein by reference for all purposes.

### BACKGROUND

The present inventive concept relates to a semiconductor package.

With the trend for high performance and high integration, the number of input/output terminals of semiconductor chips is increasing, and connection pads of the semiconductor chips are arranged at different intervals depending on the design. Due to a difference in intervals between the connection pads, a difference in heights of bump structures formed on the connection pads, for flip-chip bonding, may occur. In addition, due to warpage of the semiconductor chip and the substrate, or the like, the joint gap between the substrate and the semiconductor chip may be formed unevenly. The difference in the heights of the bump structures and the unevenness of the joint gap may cause poor solder connection (for example, non-wet, slip, or the like).

### SUMMARY

Example embodiments provide a semiconductor package having improved reliability.

According to example embodiments, a semiconductor package includes a first substrate including upper pads and lower pads positioned opposite each other, and a redistribution circuit electrically connecting the upper pads and the lower pads; at least one chip structure disposed on the first substrate and including connection pads; and first bump structures disposed between the at least one chip structure and the first substrate, and electrically connecting the connection pads of the at least one chip structure and the upper pads of the first substrate. The connection pads include a first group of connection pads arranged at a first interval, and a second group of connection pads arranged at a second interval smaller than the first interval. The first bump structures include a first group of first bump structures on the first group of connection pads, and a second group of first bump structures on the second group of connection pads. Each of the first bump structures of the first group includes a first pillar contacting one of the connection pads of the first group, and a first solder connecting the first pillar and one of the upper pads. Each of the first bump structures of the second group includes a second pillar contacting one of the connection pads of the second group, a second solder contacting one of the upper pads, and a third pillar connecting the second pillar and the second solder.

According to example embodiments, a semiconductor package includes a substrate including upper pads; a chip structure disposed on the substrate and including a first group of connection pads and a second group of connection pads; and bump structures disposed between the chip structure and the substrate, and including a first group of bump structures electrically connecting the connection pads of the first group to the upper pads, and a second group of bump structures electrically connecting the connection pads of the second group to the upper pads. Each of the bump structures of the first group includes a first pillar contacting one of the connection pads of the first group and a first solder connecting the first pillar and one of the upper pads. Each of the bump structures of the second group includes a second pillar contacting one of the connection pads of the second group, a second solder contacting one of the upper pads, and a third pillar connecting the second pillar and the second solder. A diameter of the second pillar is larger than a diameter of the first pillar and a diameter of the third pillar. A sum of a height of the second pillar and a height of the third pillar is equal to or larger than a height of the first pillar.

According to example embodiments, a semiconductor package includes a substrate including upper terminals and lower terminals; an interposer substrate disposed on the substrate and including upper pads and lower pads; a plurality of chip structures disposed on the interposer substrate and including connection pads arranged in a first region and a second region; a first group of first bump structures electrically connecting the connection pads in the first region to the upper pads; a second group of first bump structures electrically connecting the connection pads in the second region to the upper pads; second bump structures disposed between the interposer substrate and the substrate and electrically connecting the lower pads of the interposer substrate and the upper terminals of the substrate; and connection bumps disposed below the substrate, and electrically connected to the lower terminals of the substrate. The interposer substrate further includes a redistribution circuit electrically connecting the connection pads in the first region of each of the plurality of chip structures to the upper terminals of the substrate, and an interconnection circuit electrically connecting the connection pads in the second region of each of the plurality of chip structures to each other. Each of the bump structures of the first group includes a first pillar contacting one of the connection pads and a first solder connecting the first pillar and one of the upper pads. Each of the bump structures of the second group includes a second pillar contacting one of the connection pads, a second solder contacting one of the upper pads, and a third pillar connecting the second pillar and the second solder.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a side cross-sectional view of a semiconductor package according to an example embodiment, and FIG. 1B is a bottom view of a chip structure of FIG. 1A;

FIGS. 2A and 2B are drawings illustrating bump structures of example modifications;

FIGS. 3A to 3D are drawings illustrating chip structures of example modifications;

FIG. 4 is a side cross-sectional view of a semiconductor package according to an example embodiment;

FIG. 5 is a side cross-sectional view of a semiconductor package according to an example embodiment;

FIG. 6 is a side cross-sectional view of a semiconductor package according to an example embodiment;

FIG. 7 is a side cross-sectional view of a semiconductor package according to an example embodiment;

FIG. 8 is a side cross-sectional view of a semiconductor package according to an example embodiment; and

FIGS. 9A to 9G are drawings illustrating a process of manufacturing bump structures of an example embodiment.

### DETAILED DESCRIPTION

Hereinafter, with reference to the accompanying drawings, example embodiments of the present inventive concept will be described as follows. Unless otherwise specified, in this specification, terms such as ‘upper’,’ ‘upper surface’,’ ‘lower’,’ ‘lower surface’,’ ‘side’ and the like are based on the drawings, and actually, may vary depending on the direction in which the components are disposed.

Additionally, ordinal numbers such as “first,” “second,” “third,” etc. may be used as labels for specific elements, steps, directions, etc. to distinguish various elements, steps, directions, etc. from each other. Terms that are not described using “first,” “second,” etc. in the specification may still be referred to as “first” or “second” in the claims. Additionally, terms (for example, “first” in a particular claim) referenced by a particular ordinal number may be described elsewhere with a different ordinal number (for example, “second” in the specification or another claim).

Like reference characters refer to like elements throughout. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

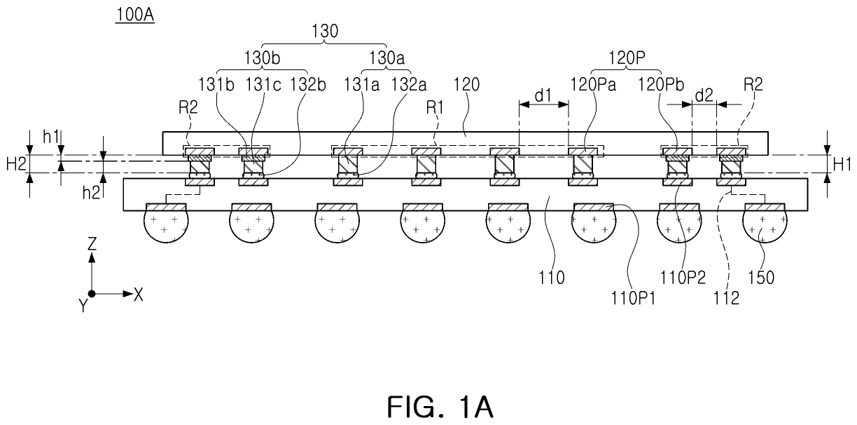

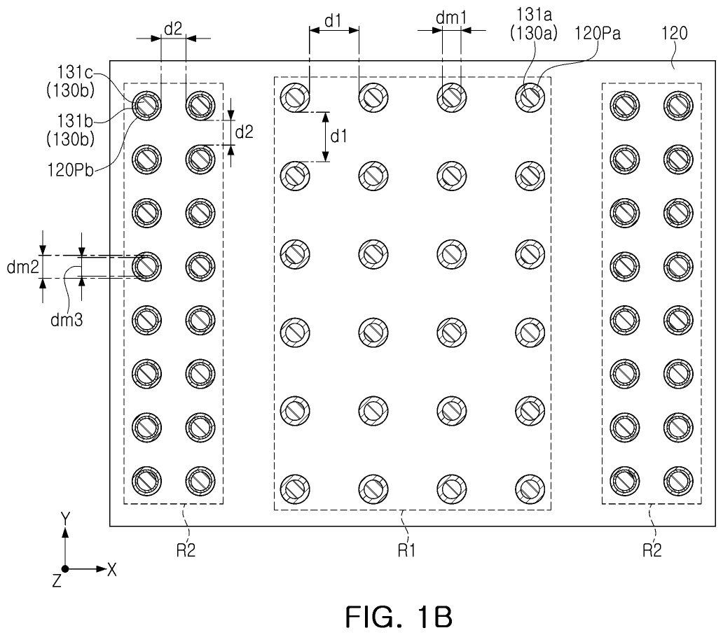

FIG. 1A is a cross-sectional side view of a semiconductor package 100A according to an example embodiment, and FIG. 1B is a bottom view of a chip structure 120 of FIG. 1A. In FIG. 1B, solder portions 132a and 132b of bump structures 130 are omitted.

Referring to FIGS. 1A and 1B, the semiconductor package 100A of an example embodiment may include a substrate 110, at least one chip structure 120, and bump structures 130.

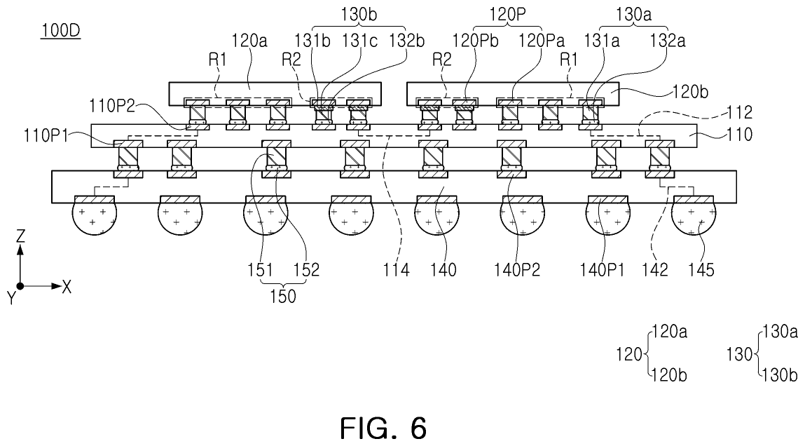

The substrate 110 may include lower pads 110P1, upper pads 110P2, and a redistribution circuit 112. The substrate 110 may include a printed circuit board (PCB), a ceramic substrate, a glass substrate, a tape substrate, and the like. The substrate 110 may be a substrate for a semiconductor package on which the chip structure 120 is mounted. In some embodiments, the substrate 110 may be an interposer substrate positioned between the substrate for a package and the chip structure (see FIGS. 6 to 8).

The lower pads 110P1 and the upper pads 110P2 may be pads positioned opposite to each other. The lower pads 110P1 may be positioned on the lower surface of the substrate 110, and the upper pads 110P2 may be positioned on the upper surface of the substrate 110. In example embodiments, lower surfaces of the lower pads 110P1 may be coplanar with the lower surface of the substrate 110, and upper surfaces of the upper pads 110P2 may be coplanar with the upper surface of the substrate 110. The lower pads 110P1 and the upper pads 110P2 may include at least one metal or an alloy composed of two or more metals among copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn). The lower pads 110P1 and the upper pads 110P2 may be electrically connected through the redistribution circuit 112. The redistribution circuit 112 may be formed of a similar material as a material of the lower pads 110P1 and the upper pads 110P2.

The upper pads 110P2 may be connected to upper bump structures 130 (which may be referred to as ‘bump structures’ or ‘first bump structures’ in this specification) disposed between the chip structure 120 and the substrate 110. The lower pads 110P1 may be connected to connection bumps 150 (which may be referred to as ‘second bump structures’ in this specification) disposed under the substrate 110. The connection bumps 150 may be solder bumps formed of, for example, tin (Sn) or an alloy (for example, Sn—Ag) including tin (Sn). According to an example embodiment, the connection bumps 150 may include a pillar and solder (see FIG. 6). According to an example embodiment, an underfill layer may be formed between the substrate 110 and the chip structure 120. The underfill layer may include a thermosetting resin such as an epoxy resin, and may seal the chip structure 120 and/or the bump structures 130 by a capillary underfill (CUF) or a molded underfill (MUF) method.

The chip structure 120 may include a semiconductor wafer and an integrated circuit (IC) formed of a semiconductor element such as silicon or germanium, or a compound semiconductor such as silicon carbide (SiC), gallium arsenide (GaAs), indium arsenide (InAs), and indium phosphide (InP). The chip structure 120 may be a bare semiconductor chip without a separate bump or wiring layer formed, but is not limited thereto, and may also be a packaged type semiconductor chip.

The chip structure 120 may include a logic chip such as a central processor (CPU), a graphic processor (GPU), a field programmable gate array (FPGA), an application processor (AP), a digital signal processor, an encryption processor, a microprocessor, a microcontroller, an analog-to-digital converter, an application-specific IC (ASIC), or a memory chip including a volatile memory such as a dynamic RAM (DRAM), a static RAM (SRAM), or a nonvolatile memory such as a phase change RAM (PRAM), a magnetic RAM (MRAM), a resistive RAM (RRAM), or a flash memory.

The chip structure 120 may be placed on a substrate 110. The chip structure 120 may include connection pads 120P for connecting to an integrated circuit. The connection pads 120P may include at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn), or an alloy composed of two or more metals. The connection pads 120P may be electrically connected to the upper pads 110P2 of the substrate 110 through the bump structures 130.

The chip structure 120 may include a first region R1 in which the first group of connection pads 120Pa are arranged, and a second region R2 in which the second group of connection pads 120Pb are arranged. In an example embodiment, the first region R1 and the second region R2 may be defined as regions in which the arrangement intervals of the connection pads 120P are different. The diameter of the second group of connection pads 120Pb that are relatively more densely disposed may be substantially the same as or smaller than the diameter of the first group of connection pads 120Pa. For example, when viewed from above, the diameters of the connection pads 120P in the first group of connection pads 120Pa may be the same as diameters of the connection pads 120P in the second group of connection pads 120Pb.

The first region R1 may be a region in which the connection pads 120P, for example, the first group of the connection pads 120Pa are arranged at a first interval d1. Within the first region R1, the first group of the connection pads 120Pa may be arranged adjacent to each other in the horizontal direction (X-direction) and the vertical direction (Y-direction). In some embodiments, the first interval d1 in the horizontal direction (X-direction) and the first interval d1 in the vertical direction (Y-direction) of the first group of the connection pads 120Pa may not be the same.

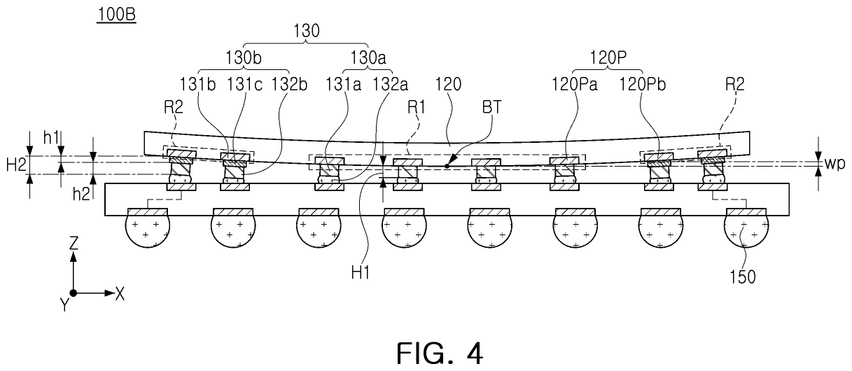

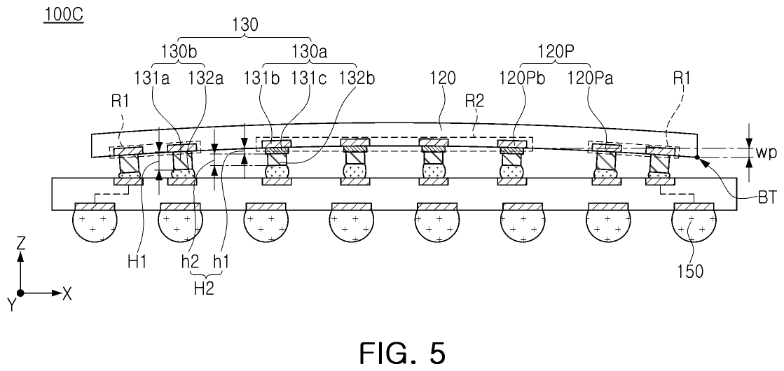

The second region R2 may be a region in which the connection pads 120P, for example, the second group of the connection pads 120Pb, are arranged at a second interval d2 smaller than the first interval d1. Within the second region R2, the second group of the connection pads 120Pb may be arranged adjacent to each other in the horizontal direction (X-direction) and the vertical direction (Y-direction). In some embodiments, the second interval d2 of the second group of the connection pads 120Pb in the horizontal direction (X-direction) and the second interval d2 in the vertical direction (Y-direction) may not be the same. In some embodiments, the second region R2 may be a region in which the step due to the bending of the chip structure 120 is larger than that of the first region R1 (for example, the example embodiments of FIGS. 4 and 5).

In an example embodiment, the second interval d2 may be equal to or less than about 0.75 times the first interval d1, for example, in a range of about 0.75 times to about 0.15 times, about 0.75 times to about 0.25 times, about 0.75 times to about 0.45 times, or the like. In this manner, a difference in the density of the plating area between the first region R1 and the second region R2 may occur due to the gap difference (about 25% or more) of the connection pads 120P, and as a result, a difference in the thickness of the plating layer may be induced in the plating process. For example, in the same plating process, the thickness in the Z direction of the pillar 131a formed in the first region R1 may be greater than the thickness in the Z direction of the pillar 131c formed in the second region R2. According to an example embodiment, by compensating for the difference in the thickness of the pillar in the first region R1 and the second region R2, the connection reliability of the bump structures 130 may be improved.

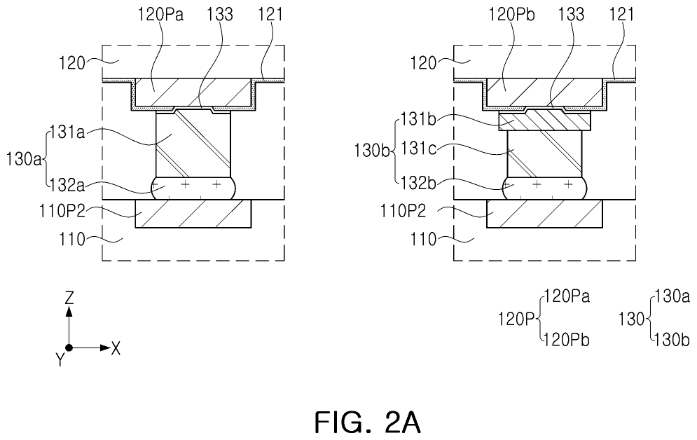

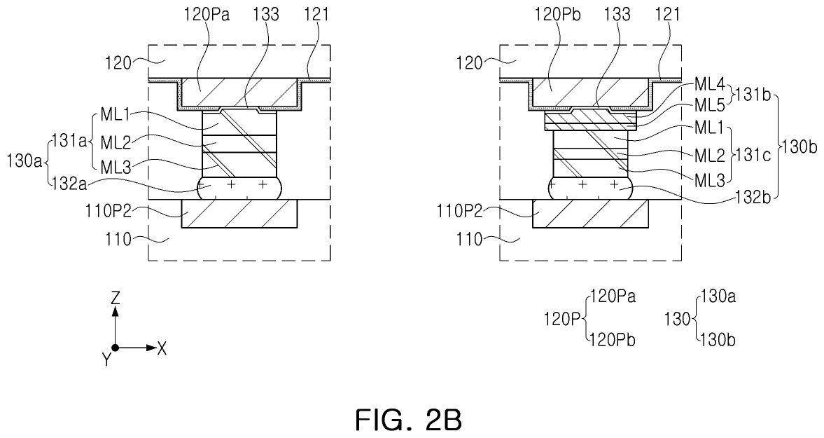

Bump structures 130 may be disposed between the chip structure 120 and the substrate 110. The bump structures 130 may electrically connect the connection pads 120P of the chip structure 120 and the upper pads 110P2 of the substrate 110. The bump structures 130 may include at least one metal or an alloy of two or more metals selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn). The bump structures 130 may be composed of pillar portions 131a, 131b and 131c and solder portions 132a and 132b. The pillar portions 131a, 131b and 131c may be composed of a single-layer or multi-layer metal layer (see FIG. 2B).

The bump structures 130 may include a first group of bump structures 130a disposed in a first region R1 and a second group of bump structures 130b disposed in a second region R2. The first group of bump structures 130a may electrically connect the first group of connection pads 120Pa to the upper pads 110P2. Each of the first group of the bump structures 130a may include a first pillar 131a that contacts one of the first group of connection pads 120Pa and a first solder 132a that connects the first pillar 131a to one of the upper pads 110P2. The first solder 132a may contact a lower surface of the first pillar 131a and an upper surface of the upper pad 110P2. The second group of the bump structures 130b may electrically connect the second group of the connection pads 120Pb to the upper pads 110P2. Each of the second group of the bump structures 130b may include a second pillar 131b that contacts one of the second group of the connection pads 120Pb, a second solder 132b that contacts one of the upper pads 110P2, and a third pillar 131c that connects the second pillar 131b and the second solder 132b. The third pillar 131c may contact a lower surface of the second pillar 131b and an upper surface of the second solder 132b.

In an example embodiment, the second pillar 131b may be formed to compensate for the height difference between the first pillar 131a and the third pillar 131c. The height H1 in the Z direction of the first pillar 131a may be greater than the height h1 in the Z direction of the second pillar 131b and the height h2 in the Z direction of the third pillar 131c, respectively. The height h1 of the second pillar 131b may be about 0.5 times or less than the height h2 of the third pillar 131c, for example, in a range of about 0.1 to about 0.5 times, about 0.2 to about 0.5 times, about 0.3 to about 0.5 times, or the like. If the height h1 of the second pillar 131b exceeds about 0.5 times the height h2 of the third pillar 131c, it may rather cause a height difference between the bump structures 130a of the first group and the bump structures 130b of the second group. For example, the height h1 of the second pillar 131b may be in the range of about 2 μm to about 10 μm, but the height h1 of the second pillar 131b may be determined by considering a height difference between the first pillar 131a and the third pillar 131c, and a joint gap difference in the first region R1 and the second region R2 (see FIGS. 4 and 5). The sum H2 of the height h1 of the second pillar 131b and the height h2 of the third pillar 131c may be equal to or greater than the height H1 of the first pillar 131a.

In an example embodiment, the second pillar 131b may be formed to secure an alignment margin of the third pillar 131c. The diameter dm2 of the second pillar 131b may be larger than the diameter dm3 of the third pillar 131c. The diameter dm3 of the third pillar 131c may be substantially the same as or smaller than the diameter dm1 of the first pillar 131a. The second diameter dm2 may be about 1.05 times or more, for example, in a range of about 1.05 times to 1.1 times the third diameter dm3. When the second diameter dm2 exceeds about 1.1 times the third diameter dm3, a short circuit may occur between adjacent second pillars 131b.

FIGS. 2A and 2B are drawings illustrating bump structures 130 of example modifications.

Referring to FIG. 2A, in an example modification, a seed layer 133 may be disposed between the bump structures 130 and the connection pads 120P. The seed layer 133 may include titanium (Ti), copper (Cu), or the like. The bump structures 130 may be metal structures formed by an electroplating process using the seed layer 133. The chip structure 120 may further include a passivation layer 121 that exposes at least a portion of the connection pads 120P. For example, the passivation layer 121 may contact side and lower surfaces of the connection pads 120P. The seed layer 133 may conformally extend along the surfaces of the passivation layer 121 and the connection pads 120P. For example, the seed layer 133 may contact the surfaces of the passivation layer 121 and the portion of the connection pads 120P exposed by the passivation layer 121. Each of the bump structures 130a of the first group may include a first pillar 131a in contact with the seed layer 133 and a first solder 132a connecting the first pillar 131a to one of the upper pads 110P2. Each of the bump structures 130b of the second group may include a second pillar 131b in contact with the seed layer 133, a second solder 132b in contact with one of the upper pads 110P2, and a third pillar 131c connecting the second pillar 131b to the second solder 132b. In example embodiments, side surfaces of the first pillar 131a and the seed layer 133 may be aligned in the Z direction, and side surfaces of the second pillar 131b and the seed layer 133 may be aligned in the Z direction.

Referring to FIG. 2B, in an example variation, at least some pillars 131a, 131b and 131c may include two or more metal layers stacked in a vertical direction (Z-direction). The first pillar 131a of the first group of bump structures 130a and the third pillar 131c of the second group of bump structures 130b may include metal layers corresponding to each other. The first pillar 131a and the third pillar 131c may include a first metal layer ML1, a second metal layer ML2, and a third metal layer ML3 that are sequentially laminated toward the solder portions 132a and 132b. The first metal layer ML1 may include copper (Cu), the second metal layer ML2 may include nickel (Ni), and the third metal layer ML3 may include copper (Cu). The second pillar 131b may include a fourth metal layer ML4 and a fifth metal layer ML5 that are laminated between the seed layer 133 and the third pillar 131c. The fourth metal layer ML4 may include copper (Cu), and the fifth metal layer ML5 may include nickel (Ni). Depending on example embodiments, the pillars 131a, 131b and 131c may include less or more metal layers than those described above, or may include other metals than those described above. For example, the metal layers may include at least one of copper (Cu), aluminum (Al), silver (Ag), tin (Sn), gold (Au), nickel (Ni), lead (Pb), and titanium (Ti).

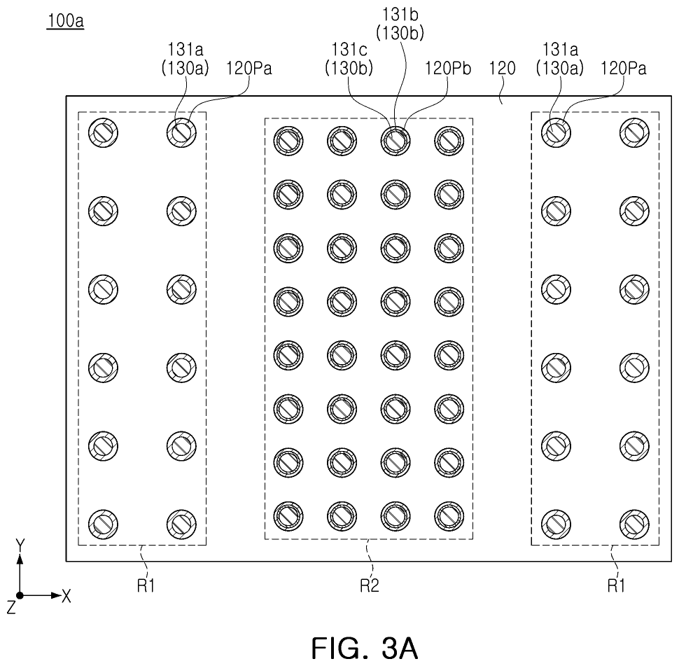

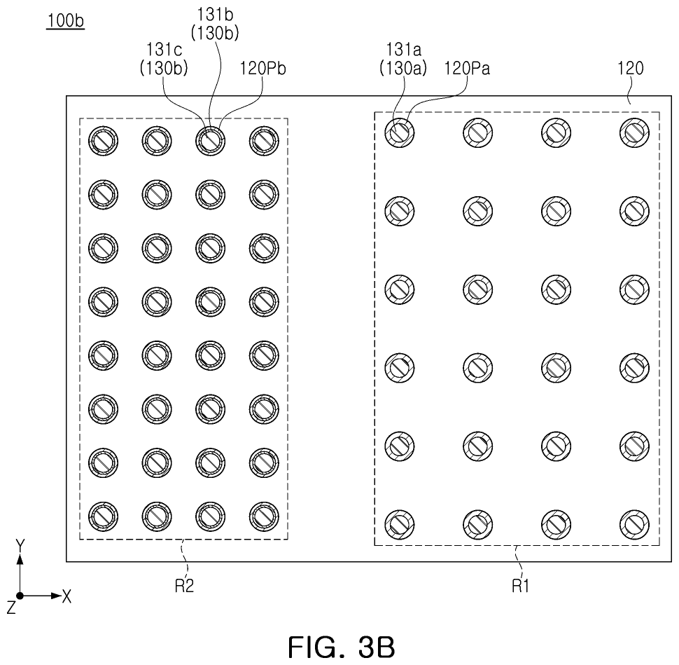

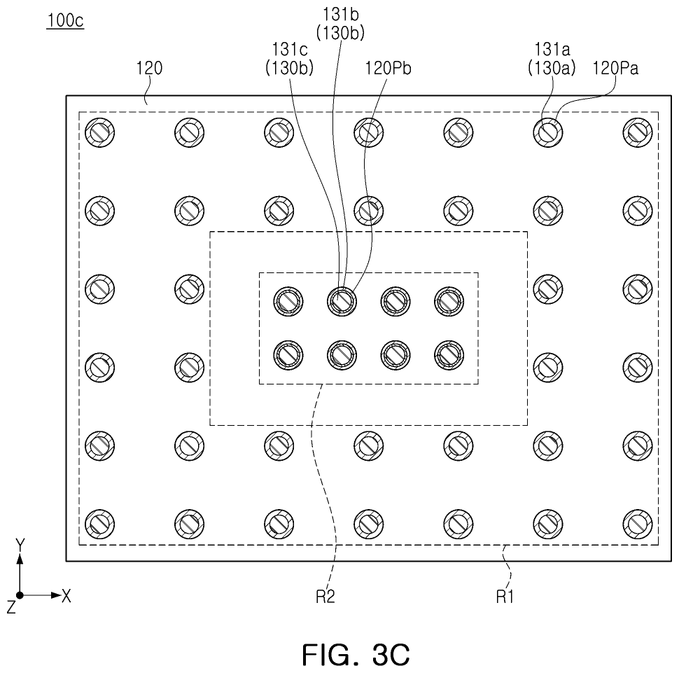

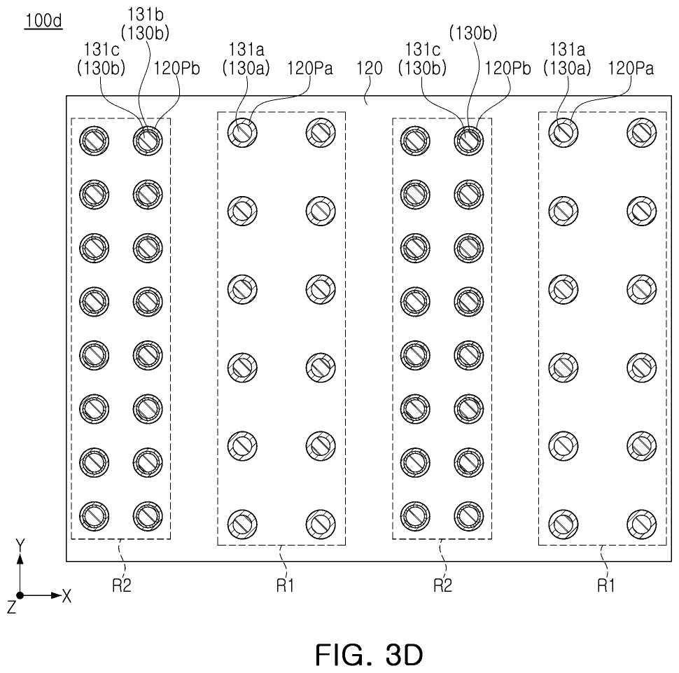

FIGS. 3A to 3D are drawings illustrating chip structures 120 of example modifications. FIGS. 3A to 3D schematically illustrate various arrangement forms of the first region R1 and the second region R2. In each of the embodiments of FIGS. 3A to 3D, the first region R1 may be a region in which the first group of connection pads 120Pa are arranged at a first interval, and the second region R2 may be a region in which the second group of connection pads 120Pb are arranged at a second interval d2 smaller than the first interval d1.

Referring to FIG. 3A, in the chip structure 120 of an example modification, the first regions R1 may be disposed adjacent to at least two sides of the second region R2. For example, the second region R2 may be disposed adjacent to upper and lower edges of the chip structure 120 in the vertical direction (Y-direction), and the first regions R1 may be disposed adjacent to both sides of the second region R2 in the horizontal direction (X-direction). As described above with reference to FIGS. 1A and 1B, the first group of connection pads 120Pa in the first region R1 and the second group of connection pads 120Pb in the second region R2 may be disposed at different intervals. The first group of bump structures 130a in the first region R1 may include first pillars 131a disposed on the first group of connection pads 120Pa. The second group of bump structures 130b disposed within the second region R2 may include second pillars 131b and third pillars 131c laminated on the second group of connection pads 120Pb.

Referring to FIG. 3B, in the chip structure 120 of an example modification, the first region R1 and the second region R2 may be respectively disposed adjacent to the edges of the chip structure 120. For example, the first region R1 may be disposed adjacent to the first edge of the chip structure 120 in the horizontal direction (X-direction), and the second region R2 may be disposed adjacent to the second edge of the chip structure 120 located opposite the first edge in the horizontal direction (X-direction).

Referring to FIG. 3C, in the chip structure 120 of an example modification, the second region R2 may be disposed only in a local region of the chip structure 120. For example, the second region R2 may be disposed in a central region of the chip structure 120, and the first region R2 may be disposed in a peripheral region surrounding the central region of the chip structure 120.

Referring to FIG. 3D, in the chip structure 120 of an example modification, the first region R1 and the second region R2 may each include a plurality of regions that are not continuous. For example, the first region R1 and the second region R2 may be alternately disposed in at least one direction, for example, the horizontal direction (X-direction).

In this manner, the chip structure 120 applied to example embodiments may include the first region R1 and the second region R2 arranged in various forms.

FIG. 4 is a cross-sectional side view of a semiconductor package 100B according to an example embodiment.

Referring to FIG. 4, the semiconductor package 100B of an example embodiment may have the same or similar features as those described with reference to FIGS. 1A to 3D, except that the second group of bump structures 130b are introduced to compensate for the step of the chip structure 120. The chip structure 120 may have a warpage in which both ends are raised upward. In an example embodiment, the second region R2 may be a region in which a step (wp) is large from the lowest end (BT) of the chip structure 120 due to the warpage. A joint gap between the chip structure 120 and the substrate 110 in the second region R2 may be larger than a joint gap in the first region R1. For example, the first region R1 may have a step (wp) of less than 2 μm from the lowest end (BT) of the chip structure 120 in the vertical direction (Z-direction), and the second region R2 may have a step (wp) of 2 μm or more from the lowest end (BT) of the chip structure 120 in the vertical direction (Z-direction).

Even when the height difference between the first pillar 131a and the third pillar 131c is not large due to the gap difference (less than about 25%) of the connection pads 120P, the second pillar 131b may be formed to compensate for the step (wp) of the second region R2. In some embodiments, the height H1 of the first pillar 131a may be substantially the same as the height h2 of the third pillar 131c. The height h1 of the second pillar 131b may be in a range of about 2 μm to about 10 μm. The height h1 of the second pillar 131b may be determined in consideration of the step (wp) of the second region R2. In this case, the sum H2 of the height h1 of the second pillar 131b and the height h2 of the third pillar 131c may be greater than the height H1 of the first pillar 131a.

FIG. 5 is a cross-sectional side view of a semiconductor package 100C according to an example embodiment.

Referring to FIG. 5, the semiconductor package 100C of an example embodiment may have the same or similar features as those described with reference to FIGS. 1A to 4, except that the warpage direction of the chip structure 120 is different from the example embodiment of FIG. 4. The chip structure 120 may have a warpage in which both ends are lowered downward. In the example embodiment, the second region R2 may be a region in which the step (wp) is large due to the warpage and the lowest end (BT) of the chip structure 120. For example, the first region R1 may have a step (wp) of less than 2 μm from the lowest end (BT) of the chip structure 120 in the vertical direction (Z-direction), and the second region R2 may have a step (wp) of 2 μm or more from the lowest end (BT) of the chip structure 120 in the vertical direction (Z-direction).

In some embodiments, the height H1 of the first pillar 131a may be substantially the same as the height h2 of the third pillar 131c. The height h1 of the second pillar 131b may be in a range of about 2 μm to about 10 μm. The height h1 of the second pillar 131b may be determined in consideration of the step (wp) of the second region R2. In this case, the sum H2 of the height h1 of the second pillar 131b and the height h2 of the third pillar 131c may be greater than the height H1 of the first pillar 131a.

FIG. 6 is a cross-sectional side view of a semiconductor package 100D according to an example embodiment.

Referring to FIG. 6, the semiconductor package 100D of an example embodiment may have the same or similar features as those described with reference to FIGS. 1A to 5, except that it further includes a second substrate 140 on which the first substrate 110 is mounted. The semiconductor package 100D may include a plurality of chip structures 120, a first substrate 110, first bump structures 130, a second substrate 140, and second bump structures 150.

The plurality of chip structures 120 may each include a first region R1 and a second region R2 described with reference to FIGS. 1A to 5. A plurality of chip structures 120 are disposed in a horizontal direction (for example, X-direction) on a first substrate 110 and may be electrically connected to each other through the first substrate 110. For example, the plurality of chip structures 120 may include a first chip structure 120a and a second chip structure 120b. The first chip structure 120a and the second chip structure 120b may include different types of semiconductor chips. For example, the first chip structure 120a may include a logic chip such as a central processor (CPU), a graphic processor (GPU), a field programmable gate array (FPGA), a digital signal processor, an encryption processor, a microprocessor, a microcontroller, an analog-to-digital converter, an ASIC, and the like, and the second chip structure 120b may include a memory chip such as a DRAM, an SRAM, a PRAM, a ReRAM, an FeRAM, an MRAM, a flash memory. According to an example embodiment, the second chip structure 120b may be provided as a high-performance memory device such as an High bandwidth memory (HBM), an Hybrid memory cube (HMC), and the like.

The first substrate 110 is disposed between the plurality of chip structures 120 and the second substrate 140 and may be referred to as an interposer substrate. In some embodiments, the first substrate 110 may be a silicon interposer substrate including a through silicon via (TSV). The first substrate 110 may include a redistribution circuit 112 electrically connecting the plurality of chip structures 120 to the second substrate 140, and an interconnection circuit 114 electrically connecting the plurality of chip structures 120 to each other. The redistribution circuit 112 may electrically connect connection pads 120P disposed within respective first regions R1 of the first chip structure 120a and the second chip structure 120b to upper terminals 140P2 of the second substrate 140. The interconnection circuit 114 may connect the connection pads 120P disposed in respective second regions R2 of the first chip structure 120a and the second chip structure 120b to each other.

The first bump structures 130 may include a first group of first bump structures 130a disposed on the first region R1 and a second group of first bump structures 130b disposed on the second region R2. The second group of first bump structures 130b may include second pillars 131b configured to compensate for the height difference between the first pillar 131a and the third pillar 131c and/or the step of the chip structure 120.

The second substrate 140 may include lower terminals 140P1, upper terminals 140P2, and a wiring circuit 142. Upper surfaces of the upper terminals 140P2 may be coplanar with upper surfaces of the second substrate 140, and lower surfaces of the lower terminals 140P1 may be coplanar with lower surfaces of the second substrate 140. The lower terminals 140P1 and the upper terminals 140P2 may be electrically connected to each other through the wiring circuit 142. The second substrate 140 may be connected to an external device, such as a module substrate or a system board, through connection bumps 145. The connection bumps 145 may be disposed on the lower terminals 140P1. For example, the connection bumps 145 may be solder bumps formed of tin (Sn) or an alloy including tin (Sn). According to an example embodiment, the connection bumps 145 may include a pillar and solder.

The second bump structures 150 may be disposed between the first substrate 110 and the second substrate 140. The second bump structures 150 may electrically connect the lower pads 110P1 of the first substrate 110 and the upper terminals 140P2 of the second substrate 140. The second bump structures 150 may include a pillar 151 connected to the lower pads 110P1 and a solder 152 connecting the pillar 151 and the upper terminals 140P2. For example, the pillars 151 may contact lower surfaces of the lower pads 110P1, and the solders 152 may contact lower surfaces of the pillars 151 and upper surfaces of the upper terminals 140P2.

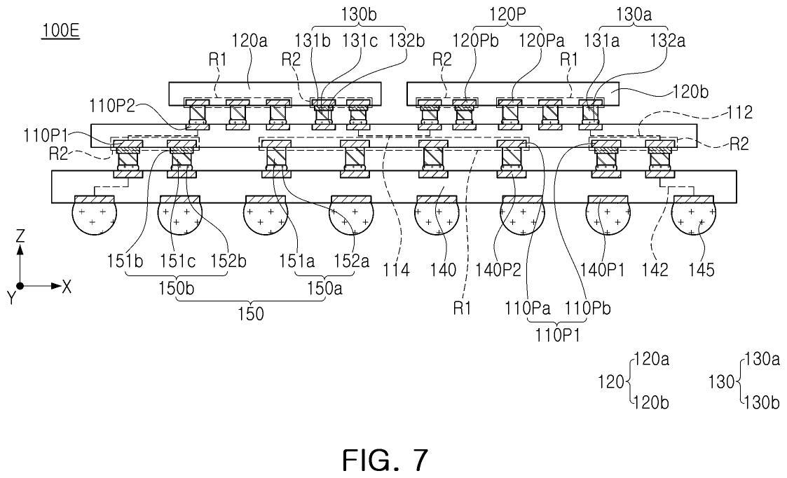

FIG. 7 is a cross-sectional side view of a semiconductor package 100E according to an example embodiment.

Referring to FIG. 7, the semiconductor package 100E of an example embodiment may have the same or similar features as described with reference to FIGS. 1A to 6, except that the second bump structures 150 include the second bump structures 150a of the first group and the second bump structures 150b of the second group. The second bump structures 150b of the second group may include the fifth pillars 151b configured to compensate for the height difference between the fourth pillar 151a and the sixth pillar 151c and/or the step of the first substrate 110. The second bump structures 150 may include the second bump structures 150a of the first group disposed within the first region R1 and the second bump structures 150b of the second group disposed within the second region R2. The second bump structures 150a of the first group may electrically connect the lower pads 110Pa of the first group to the upper terminals 140P2. Each of the second bump structures 150a of the first group may include a fourth pillar 151a and a third solder 152a. The second bump structures 150b of the second group may electrically connect the lower pads 110Pb of the second group to the upper terminals 140P2. Each of the second bump structures 150b of the second group may include a fifth pillar 151b, a fourth solder 152b, and a sixth pillar 151c. It can be understood that the second bump structures 150a of the first group and the second bump structures 150b of the second group have similar characteristics to the first bump structures 130a of the first group and the first bump structures 130b of the second group, respectively.

In FIG. 7, the first region R1 may be a region in which the lower pads 110Pa are arranged at a first interval, and the second region R2 may be a region in which the lower pads 110Pb are arranged at a second interval d2 smaller than the first interval d1.

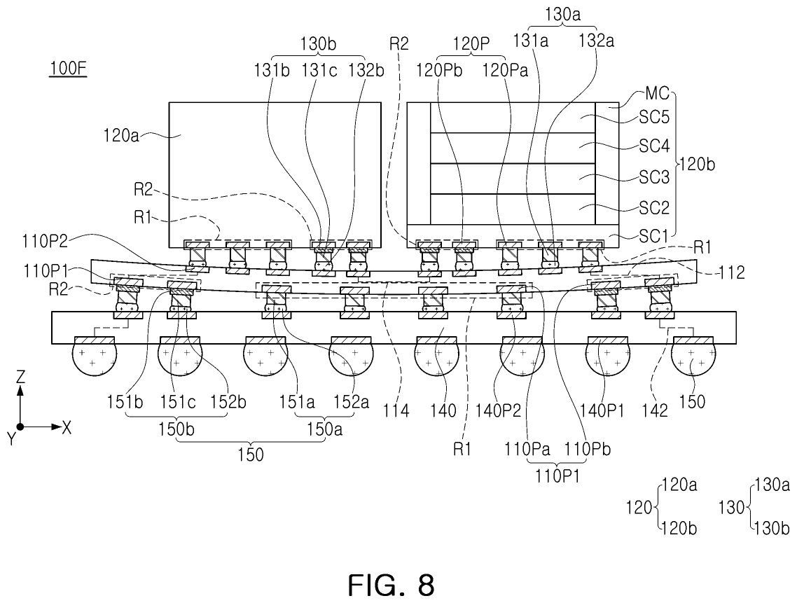

FIG. 8 is a cross-sectional side view of a semiconductor package 100F according to an example embodiment.

Referring to FIG. 8, the semiconductor package 100F of an example embodiment may have the same or similar features as those described with reference to FIGS. 1A to 7, except that the first bump structures 130 are disposed according to the arrangement of the corresponding connection pads 120P, and the second bump structures 150 are disposed according to the warpage of the first substrate 110.

The plurality of chip structures 120 may include a first region R1 in which the first group of connection pads 120Pa are disposed, and a second region R2 in which the second group of connection pads 120Pb are disposed. The first region R1 may be a region in which the first group of connection pads 120Pa are arranged at a first interval. The second region R2 may be a region in which the second group of connection pads 120Pb are arranged at a second interval d2 smaller than the first interval d1.

The first substrate 110 may include a first region R1 where the first group of lower pads 110Pa are disposed, and a second region R2 where the second group of lower pads 110Pb are disposed. The first region R1 may be a region having a first step in the vertical direction (Z-direction) from the lowest end of the first substrate 110. The second region R2 may be a region having a second step larger than the first step in the vertical direction (Z-direction) from the lowest end of the first substrate 110. The second bump structures 150b of the second group may include fifth pillars 151b configured to compensate for the step of the first substrate 110.

The first chip structure 120a may be a processor chip including, for example, a central processor (CPU), a graphic processor (GPU), a field programmable gate array (FPGA), a digital signal processor (DSP), an encryption processor, a microprocessor, a microcontroller, an analog-to-digital converter, an application-specific integrated circuit (ASIC), and the like.

The second chip structure 120b may include a plurality of semiconductor chips SC1, SC2, SC3, SC4, and SC5 and a mold layer (MC). The plurality of semiconductor chips SC1, SC2, SC3, SC4, and SC5 may be provided in a greater or lesser number than that illustrated in the drawing. The plurality of semiconductor chips SC1, SC2, SC3, SC4, and SC5 may be stacked in a vertical direction (Z-direction) by a thermocompression bonding method or a hybrid bonding method. The plurality of semiconductor chips SC1, SC2, SC3, SC4, and SC5 may be interconnected through TSVs. A plurality of semiconductor chips SC1, SC2, SC3, SC4, and SC5 may include a buffer chip (for example, SC1) and a plurality of memory chips (for example, SC2, SC3, SC4, and SC5). The mold layer (MC) may include an insulating material, such as, for example, Epoxy Molding Compound (EMC).

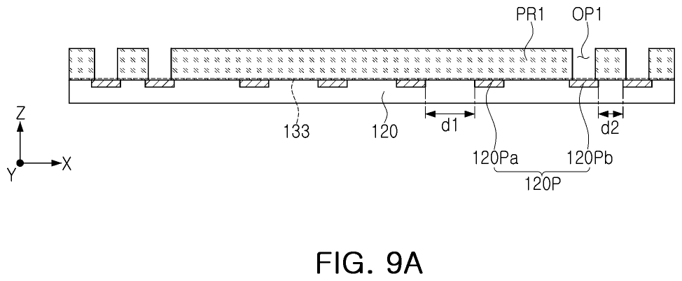

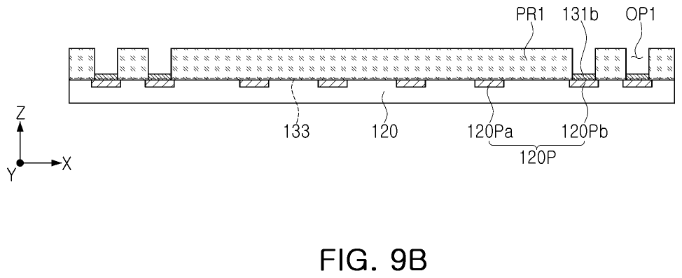

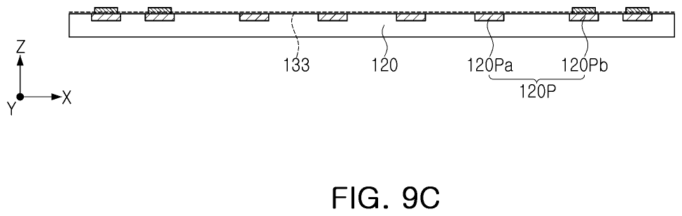

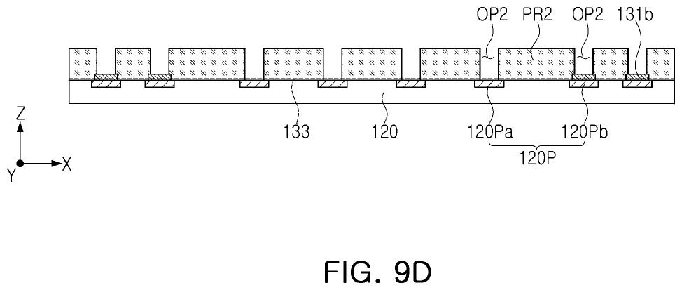

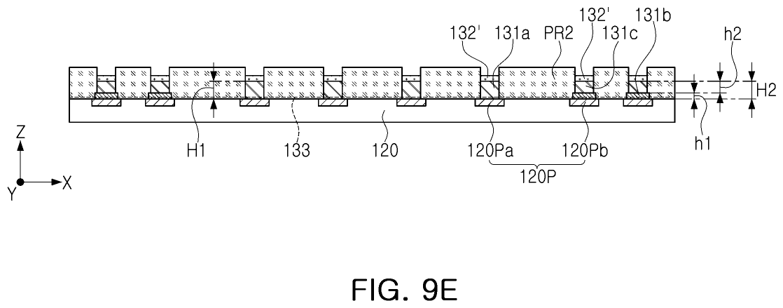

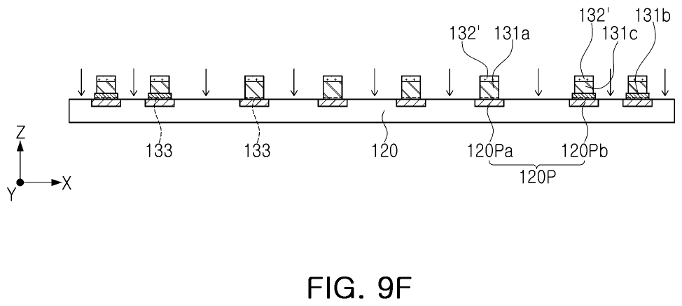

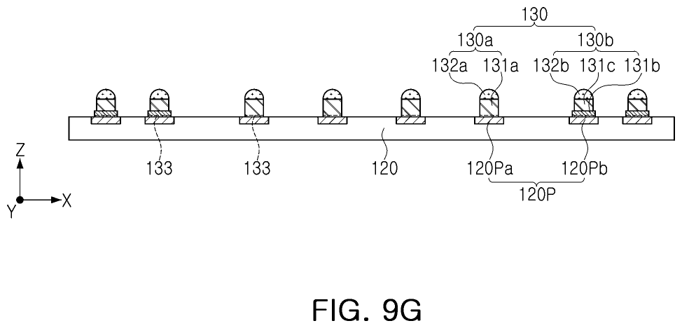

FIGS. 9A to 9G are drawings illustrating a manufacturing process of bump structures 130 of an example embodiment.

Referring to FIG. 9A, a seed layer 133 and a first mask pattern PR1 may be formed on a chip structure 120. The seed layer 133 may be formed by performing an electroless plating process or a deposition process. The seed layer 133 may include a metal such as copper (Cu) or titanium (Ti). The first mask pattern PR1 may be formed on the seed layer 133. The first mask pattern PR1 may include a photosensitive material. The first mask pattern PR1 may include first openings OP1 formed by performing an exposure process, a development process, or the like. The first openings OP1 may expose the second group of connection pads 120Pb. The second group of connection pads 120Pb may be arranged at a second interval d2 smaller than a first interval d1. The first group of connection pads 120Pa may be arranged at the first interval d1. In some embodiments, when the first interval d1 and the second interval d2 are the same, the second group of connection pads 120Pb may be pads disposed in an area where a warpage of about 2 μm or more is expected.

Referring to FIG. 9B, a first pillar 131b may be formed within the first mask pattern PR1. For example, first pillars 131b may be formed within the first openings OP1 and on the second group of connection pads 120Pb. The first pillar 131b may be formed by performing a descum process and an electroplating process using a seed layer 133. The first pillar 131b may be composed of a single layer or multiple layers of metal layers. For example, the first pillar 131b may be a single layer including copper (Cu) or a multiple layer including copper (Cu) and nickel (Ni).

Referring to FIG. 9C, the first mask pattern PR1 may be removed. The first mask pattern PR1 may be removed by performing an ashing process. After the first mask pattern PR1 is removed, the seed layer 133 and the first pillar 131b may be exposed.

Referring to FIG. 9D, the second mask pattern PR2 may be formed on the seed layer 133. The second mask pattern PR2 may include second openings OP2 formed by performing an exposure process, a development process, and the like. The second openings OP2 may be aligned on the connection pads 120Pa of the first group and the connection pads 120Pb of the second group. The second openings OP2 may expose the seed layer 133 on the connection pads 120Pa of the first group and the first pillar 131b on the connection pads 120Pb of the second group.

Referring to FIGS. 9E and 9F, the second pillars 131a and 131c and the preliminary solder 132′ may be formed within the second mask pattern PR2. The second pillars 131a and 131c and the preliminary solder 132′ may be formed by performing a descum process and an electroplating process using the seed layer 133. The second pillars 131a and 131c may be a single layer including copper (Cu) or a multilayer including copper (Cu) and nickel (Ni). The preliminary solder 132′ may include an alloy (for example, Sn—Ag) containing tin (Sn). The height H1 of the first pillar 131a may be greater than the height h3 of the third pillar 131c. The sum H2 of the height h1 of the second pillar 131b and the height h3 of the third pillar 131c may be substantially equal to or greater than the height H1 of the first pillar 131a. In this case, ‘substantially equal’ is a concept including tolerance and may mean not being intentionally designed differently. Thereafter, the second mask pattern PR2 may be removed. After the second mask pattern PR2 is removed, a portion of the exposed seed layer 133 may be etched.

Referring to FIG. 9G, solder portions 132a and 132b may be formed on the first pillar 131a and the third pillar 131c. The solder portions 132a and 132b may be formed by a reflow process. The first group of bump structures 130a may include a first pillar 131a and a first solder 132a laminated on the first group of connection pads 120Pa. The second group of bump structures 130b may include a second pillar 131b, a third pillar 131c, and a second solder 132b laminated on the second group of connection pads 120Pb. The bump structure 130b of the second group may include second pillars 131b configured to compensate for the height difference between the first pillar 131a and the third pillar 131c and/or the step of the chip structure 120.

As set forth above, according to example embodiments, a semiconductor package having improved reliability may be provided by introducing bump structures of various heights.

While example embodiments have been illustrated and described above, it will be apparent to those skilled in the art that modifications and variations could be made without departing from the scope of the present inventive concept as defined by the appended claims.

What is claimed is:

1. A semiconductor package comprising:
a first substrate including upper pads and lower pads opposite to each other, and a redistribution circuit electrically connecting the upper pads and the lower pads;
at least one chip structure disposed on the first substrate and including connection pads; and
first bump structures disposed between the at least one chip structure and the first substrate, and electrically connecting the connection pads of the at least one chip structure and the upper pads of the first substrate,
wherein the connection pads include a first group of connection pads arranged at a first interval, and a second group of connection pads arranged at a second interval smaller than the first interval,
wherein the first bump structures include a first group of first bump structures on the first group of connection pads, and a second group of first bump structures on the second group of connection pads,
wherein each of the first group of the first bump structures includes a first pillar contacting one of the first group of the connection pads, and a first solder connecting the first pillar and one of the upper pads, and
wherein each of the second group of the first bump structures includes a second pillar contacting one of the second group of the connection pads, a second solder contacting one of the upper pads, and a third pillar connecting the second pillar and the second solder.

2. The semiconductor package of claim 1, wherein the second interval is about 0.75 times or less than the first interval.

3. The semiconductor package of claim 1, wherein a first height of the first pillar is greater than a second height of the second pillar and a third height of the third pillar.

4. The semiconductor package of claim 3, wherein a sum of the second height of the second pillar and the third height of the third pillar is equal to or greater than the first height of the first pillar.

5. The semiconductor package of claim 1, wherein a second height of the second pillar is about 0.5 times or less than a third height of the third pillar.

6. The semiconductor package of claim 5, wherein the second height is in a range of about 2 μm to about 10 μm.

7. The semiconductor package of claim 1, wherein a first diameter of the first pillar and a third diameter of the third pillar are smaller than a second diameter of the second pillar.

8. The semiconductor package of claim 7, wherein the second diameter is about 1.05 times or more the third diameter.

9. The semiconductor package of claim 7, wherein the first diameter is equal to or larger than the third diameter.

10. The semiconductor package of claim 1, wherein the first pillar and the third pillar include two or more metal layers stacked in a vertical direction.

11. The semiconductor package of claim 10, wherein the two or more metal layers include at least one of copper, aluminum, silver, tin, gold, nickel, lead, and titanium.

12. The semiconductor package of claim 1, further comprising:
a second substrate disposed below the first substrate, and including upper terminals and lower terminals opposite to each other, and a wiring circuit connecting the upper terminals and the lower terminals; and
second bump structures disposed between the first substrate and the second substrate, and electrically connecting lower pads of the first substrate and the upper terminals of the second substrate.

13. The semiconductor package of claim 12,
wherein the at least one chip structure is provided as a plurality of chip structures disposed on the first substrate, and
wherein the first substrate further includes an interconnection circuit electrically connecting the plurality of chip structures to each other.

14. The semiconductor package of claim 12,
wherein the lower pads include a first group and a second group,
wherein the second bump structures include a first group on the first group of the lower pads and a second group on the second group of the lower pads,
wherein each of the first group of the second bump structures includes a fourth pillar contacting one of the first group of the lower pads, and a third solder connecting the fourth pillar and one of the upper terminals, and
wherein each of the second group of the second bump structures includes a fifth pillar contacting one of the second group of the lower pads, a fourth solder contacting one of the upper pads, and a sixth pillar connecting the fifth pillar and the fourth solder.

15. The semiconductor package of claim 14,
wherein the first substrate includes a first region in which the first group of the lower pads are disposed, and a second region in which the second group of the lower pads are disposed,
wherein the first substrate is bent so that both ends face upward or downward,
wherein the first region has a first step from a lowermost end of the first substrate in a vertical direction, and
wherein the second region has a second step greater than the first step, from the lowermost end of the first substrate in a vertical direction.

16. A semiconductor package comprising:
a substrate including upper pads;
a chip structure disposed on the substrate and including a first group of connection pads and a second group of connection pads; and
bump structures disposed between the chip structure and the substrate, and including a first group of bump structures electrically connecting the first group of the connection pads to the upper pads, and a second group of bump structures electrically connecting the second group of the connection pads to the upper pads,
wherein each of the first group of the bump structures includes a first pillar contacting one of the first group of the connection pads and a first solder connecting the first pillar and one of the upper pads,
wherein each of the second group of the bump structures includes a second pillar contacting one of the second group of the connection pads, a second solder contacting one of the upper pads, and a third pillar connecting the second pillar and the second solder,
wherein a diameter of the second pillar is larger than a diameter of the first pillar and a diameter of the third pillar, and
wherein a sum of a height of the second pillar and a height of the third pillar is equal to or larger than a height of the first pillar.

17. The semiconductor package of claim 16, wherein a first interval between the first group of the connection pads is larger than a second interval between the second group of the connection pads.

18. The semiconductor package of claim 16,
wherein the chip structure includes a first region in which the first group of the connection pads are disposed, and a second region in which the second group of the connection pads are disposed,
wherein the first region has a step of less than 2 μm in a vertical direction from a lowermost end of the chip structure, and
wherein the second region has a step of 2 μm or more in the vertical direction from the lowermost end of the chip structure.

19. A semiconductor package comprising:
a substrate including upper terminals and lower terminals;
an interposer substrate disposed on the substrate and including upper pads and lower pads;
a plurality of chip structures disposed on the interposer substrate and including connection pads arranged in a first region and a second region;
a first group of first bump structures electrically connecting the connection pads in the first region to the upper pads;
a second group of first bump structures electrically connecting the connection pads in the second region to the upper pads;
second bump structures disposed between the interposer substrate and the substrate and electrically connecting the lower pads of the interposer substrate and the upper terminals of the substrate; and
connection bumps disposed below the substrate, and electrically connected to the lower terminals of the substrate,
wherein the interposer substrate further includes a redistribution circuit electrically connecting the connection pads in the first region of each of the plurality of chip structures to the upper terminals of the substrate, and an interconnection circuit electrically connecting the connection pads in the second region of each of the plurality of chip structures to each other,
wherein each of the first group of the first bump structures includes a first pillar contacting one of the connection pads and a first solder connecting the first pillar and one of the upper pads, and
wherein each of the second group of the first bump structures includes a second pillar contacting one of the connection pads, a second solder contacting one of the upper pads, and a third pillar connecting the second pillar and the second solder.

20. The semiconductor package of claim 19,
wherein the first region is a region in which the connection pads are arranged at a first interval, or a region having a step of less than about 2 μm from a lowermost end of a corresponding chip structure among the plurality of chip structures in a vertical direction, and
wherein the second region is a region in which the connection pads are arranged at a second interval, smaller than the first interval, or a region having a step of about 2 μm or more from a lowermost end of a corresponding chip structure among the plurality of chip structures.
